(19) United States
(12) Patent Application Publication
(10) Pub. No.: US 2025/0280502 A1
(43) Pub. Date: Sep. 4, 2025

(54) Modular Unit with Camera and Display

(71) Applicant: Milwaukee Electric Tool Corporation, Brookfield, WI (US)

(72) Inventors: Nolan J. Henton, Steamboat Springs, CO (US); Samuel J. Krohlow, Wauwatosa, WI (US); Christopher J. Turner, Lannon, WI (US); Tyler A. Wahl, Brookfield, WI (US)

(21) Appl. No.: 19/067,123

(22) Filed: Feb. 28, 2025

Related U.S. Application Data
(63) Continuation of application No. PCT/US2025/017615, filed on Feb. 27, 2025.
Application No. PCT/US2025/017615 is a continuation-in-part of application No. 19/049,612, filed on Feb. 10, 2025.
(60) Provisional application No. 63/559,366, filed on Feb. 29, 2024.

(51) Int. Cl. H05K 5/02; H05K 5/00

(52) U.S. Cl. CPC H05K 5/0247; H05K 5/0018; H05K 5/0086; H05K 5/0221; H05K 5/0226

(57) ABSTRACT

A device or unit with a display and camera is provided. The device includes coupling components that couple the device to stackable storage unit containers. In one embodiment, the device includes a battery interface to couple to a battery for power tools, a camera, and a display that displays images captured by the camera.

### CROSS-REFERENCE TO RELATED PATENT APPLICATIONS

The present application is a continuation of International Application No. PCT/US2025/017615, filed Feb. 27, 2025, which claims the benefit of and priority to U.S. application Ser. No. 19/049,612, filed Feb. 10, 2025, and U.S. Provisional Application 63/559,366 filed on Feb. 29, 2024, each of which is incorporated herein by reference in its entirety.

### BACKGROUND OF THE INVENTION

The present disclosure is directed generally to the field of tool storage systems and related devices. The present disclosure relates specifically to a device or unit that includes a camera, a display, and a coupling mechanism to detachably couple the device to another device or container, such as a tool storage container, in a modular tool storage system.

Tool storage units are often used to transport tools and tool accessories. Some storage units are designed to incorporate into a modular storage system. Within a modular storage system, different units, devices and/or containers may provide varying functions, such as being adapted to capture images via a camera and display the images on a display.

### SUMMARY OF THE INVENTION

One embodiment of the invention relates to a utility module including a housing, a bottom surface defined by the housing, a plurality of male couplers extending from the bottom surface, the plurality of male couplers detachably and rigidly coupling the housing to a top surface of a storage unit, a display pivotally coupled to the housing, a cable configured to extend and retract from within the housing, and a camera coupled to an outer end of the cable. The display displays one or more images captured by the camera.

Another embodiment of the invention relates to a utility module including a housing, a bottom surface defined by the housing, a plurality of male couplers extending from the bottom surface, the plurality of male couplers detachably and rigidly coupling the housing to a top surface of a storage unit, a display pivotally coupled to the housing, a camera, the display displaying one or more images captured by the camera, and a battery interface configured to physically couple to a rechargeable power tool battery. The display and camera are configured to receive power from the rechargeable power tool battery coupled to the battery interface.

Another embodiment of the invention relates to a utility module including a housing, a bottom surface defined by the housing, a plurality of male couplers extending from the bottom surface, the plurality of male couplers detachably and rigidly coupling the housing to a top surface of a storage unit, a display pivotally coupled to the housing, a storage area defined by the housing, the storage area configured to store equipment, and a camera. The display displays one or more images captured by the camera.

Another embodiment of the invention relates to a device including a housing, a bottom surface defined by the housing, a plurality of male couplers extending from the bottom surface, a display pivotally coupled to the housing, and a camera operatively coupled to the display such that images captured by the camera are viewable on the display. In a specific embodiment, the device includes a cable configured to extend and retract from within the housing, and a camera coupled to the cable. The plurality of male couplers detachably and rigidly couple the housing to a top surface of a storage unit. The display includes a screen that displays one or more images captured by the camera.

In various embodiments, the device includes a first lid pivotally coupled to the housing, the first lid and the housing collectively defining a first compartment. The cable extends out of and retracts into the first compartment.

In various embodiments, the display is pivotally coupled to the housing via the display being pivotally coupled to the first lid and the first lid being pivotally coupled to the housing.

In various embodiments, the device includes a second lid pivotally coupled to the housing, the second lid and the housing collectively defining a second compartment, and the device further includes a battery interface in the second compartment configured to physically couple to a rechargeable power tool battery. The display and camera are configured to receive power from the rechargeable power tool battery.

In various embodiments, each of the plurality of male couplers include a body extending below the bottom surface, a first tongue, and a second tongue. The first tongue and the second tongue both extend from the body and are both offset from and below the bottom surface. The first tongue defines a first channel between the bottom surface and the first tongue, and the second tongue defines a second channel between the bottom surface and the second tongue. The first channel and second channel each extend on opposing sides of the body, and each channel includes a front open end and a back closed end.

Another embodiment of the invention relates to a device including a housing, a bottom surface defined by the housing, a plurality of male couplers extending from the bottom surface, a display pivotally coupled to the housing, a camera operatively coupled to the display such that images captured by the camera are viewable on the display, and a battery interface configured to physically couple to a rechargeable power tool battery. The display includes a screen that displays one or more images captured by the camera. The plurality of male couplers detachably and rigidly couple the housing to a top surface of a storage unit. The display and camera are configured to receive power from the rechargeable power tool battery coupled to the battery interface.

Additional features and advantages will be set forth in the detailed description which follows, and will be readily apparent to those skilled in the art from the description or recognized by practicing the embodiments as described in the written description and/or shown in the accompany drawings. It is to be understood that both the foregoing general description and the following detailed description are exemplary.

The accompanying drawings are included to provide further understanding and are incorporated in and constitute a part of this specification. The drawings illustrate one or more embodiments and, together with the description, serve to explain principles and operation of the various embodiments. In addition, alternative exemplary embodiments relate to other features and combinations of features as may be generally recited in the claims.

### BRIEF DESCRIPTION OF THE DRAWINGS

This application will become more fully understood from the following detailed description, taken in conjunction with the accompanying figures, wherein like reference numerals refer to like elements in which:

FIG. 1 is a perspective view of a device including a display and camera, according to an exemplary embodiment.

FIG. 2 is a perspective view of the device of FIG. 1, according to an exemplary embodiment.

FIG. 3 is a perspective view of the device of FIG. 1, according to an exemplary embodiment.

FIG. 4 is a perspective view of the device of FIG. 1, according to an exemplary embodiment.

FIG. 5 is a perspective view from below of the device of FIG. 1, according to an exemplary embodiment.

FIG. 6 is a detailed perspective view from below of the device of FIG. 1, according to an exemplary embodiment.

FIG. 7 is a front perspective view of the device of FIG. 1 with the first and second lids removed, according to an exemplary embodiment.

FIG. 8 is a rear perspective view of the device of FIG. 1 with the first and second lids removed, according to an exemplary embodiment.

FIG. 9 is a cross-section view of the device of FIG. 1, according to an exemplary embodiment.

FIG. 10 is a front view of a portion of graphics and images shown on the display of the device of FIG. 1, according to an exemplary embodiment.

FIG. 11 is a front view of a portion of graphics and images shown on the display of the device of FIG. 1, according to an exemplary embodiment.

FIG. 12 is a front view of a portion of graphics and images shown on the display of the device of FIG. 1, according to an exemplary embodiment.

FIG. 13 is a front view of a portion of graphics shown on the display of the device of FIG. 1, according to an exemplary embodiment.

FIG. 14 is a front view of a portion of graphics and images shown on the display of the device of FIG. 1, according to an exemplary embodiment.

FIG. 15 is a front view of a portion of graphics and images shown on the display of the device of FIG. 1, according to an exemplary embodiment.

FIG. 16 is a front view of a portion of graphics and images shown on the display of the device of FIG. 1, according to an exemplary embodiment.

### DETAILED DESCRIPTION

Referring generally to the figures, an embodiment of a stackable device, container or unit is shown. One or more of the devices are configured to selectively couple and decouple with storage units. The stackable device couples with storage units and includes a camera and a display to show images captures by the camera. The display is pivotal with respect to the housing and includes an interface to receive power from a power tool battery. Applicant has observed that providing a single device that includes a camera, a display that displays images from the camera, and modular coupling components facilitates users transporting the device with other units in a modular system and using the camera to view objects that would otherwise be difficult to observe.

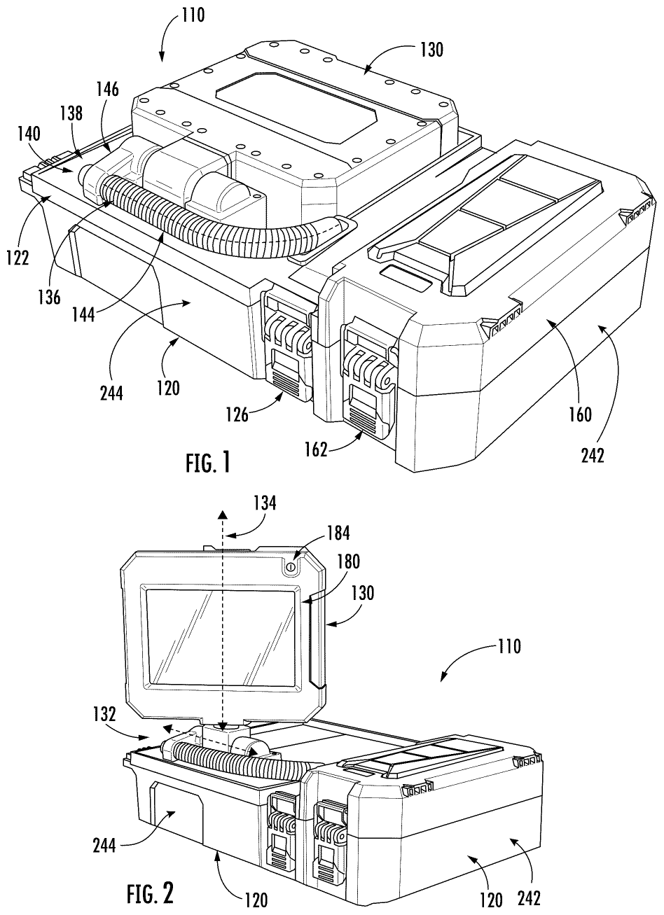

Referring to FIGS. 1-4, various aspects of utility module, shown as device 110, are shown. Device 110 includes housing 120, first lid 122 pivotally coupled to housing 120, and second lid 160 pivotally coupled to housing 120. First toggle locking latch 126 secures first lid 122 in the closed position against housing 120, and second toggle locking latch 162 secures second lid 160 in the closed position against housing 120.

Device 110 includes display 130 coupled to housing 120, such as pivotally coupled to housing 120, such as via display 130 being pivotally coupled to first lid 122 and first lid 122 being pivotally coupled to housing 120. Display 130 pivots with respect to housing about first axis 132 and second axis 134. Device 110 includes cable 136 configured to extend and retract from housing 120 via camera spring 144 from an interior end coupled to housing 120 to an outer end 138. Device 110 includes camera 140 coupled to cable 136, such as to outer end 138 of cable 136, the camera 140 receives light transmitted in the direction of outer end 138 of cable 136 (e.g., via camera 140 being at outer end 138 of cable, or via cable 136 being fiber optic and transmitting light to camera 140 at an interior end of cable). Arm 146 detachably engages with camera spring 144 to secure camera spring 144. Cable 136 extends through camera spring 144 and is extended and retracted from housing 120 via camera spring 144. Screen 180 of display 130 displays one or more images captured by camera 140.

Display 130 pivots with respect to first lid 122 and housing 120 about first axis 132, and display 130 pivots with respect to first lid 122 and housing 120 about second axis 134 distinct from first axis 132. In various embodiments, second axis 134 is perpendicular to first axis 132. In various embodiments, display 130 pivots 150 degrees with respect to housing 120 about first axis 132, and display 130 pivots 180 degrees with respect to housing 120 about second axis 134.

In various embodiments, display 130 includes a power button 184 configured to toggle whether screen 180 and camera 140 are powered. In various embodiments, display 130 is clipped and/or snapped against first lid 122, such as when display 130 is in the retracted position (FIG. 1). In various embodiments, display 130 includes a sealing gasket to provide water resistance and/or a watertight seal to protect against water entering display 130. In various embodiments, display 130 and screen 180 is a touchscreen device, thereby permitting users to touch screen 180 to provide input to device 110.

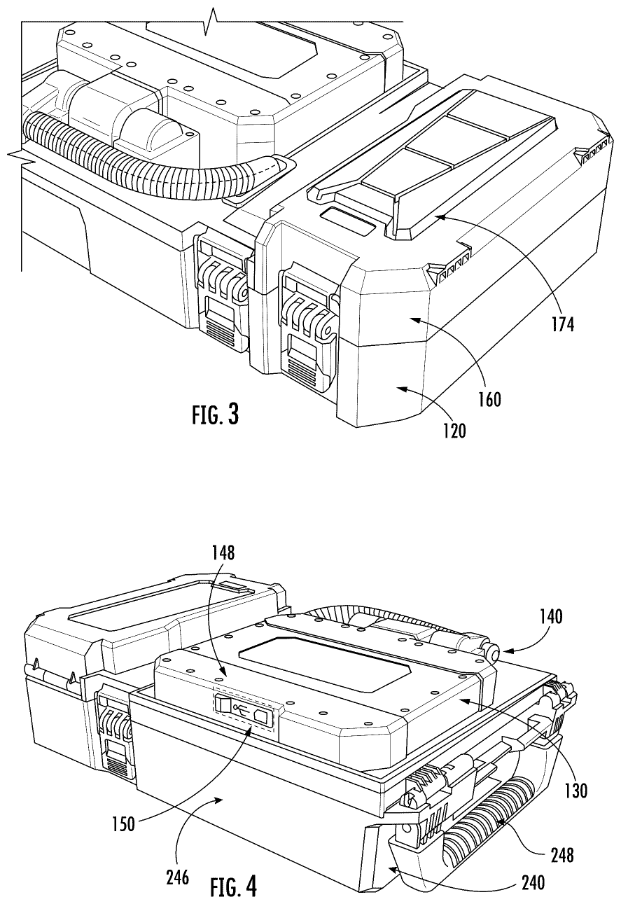

Referring to FIG. 3, in various embodiments device 110 includes knee padding 174 coupled to housing 120, such as to second lid 160 that is coupled to housing 120. Knee padding 174 provides a more comfortable position for the user to rest while the user is using device 110, such as while extending cable 136 while looking at screen 180 showing images captured by camera 140. In various embodiments, padding 174 is formed from a foam material. In various embodiments, knee padding 174 is configured to be used by a user operating the camera 140 and display 130.

Referring to FIG. 4, device 110 includes cover 150 detachably engaged with display 130 over an outlet, shown as USB outlet 148. In various embodiments, cover 150 is tethered to display 130.

Referring to FIGS. 1-5, housing 120 includes front wall 240, an opposing back wall 242, a first sidewall 244 and an opposing second sidewall 246, each of the first sidewall 244 and second sidewall 246 extending between front wall 240 and back wall 242. Device 110 includes a handle 248 coupled to housing 120, such as pivotally coupled to housing 120, such as pivotally coupled to front wall 240.

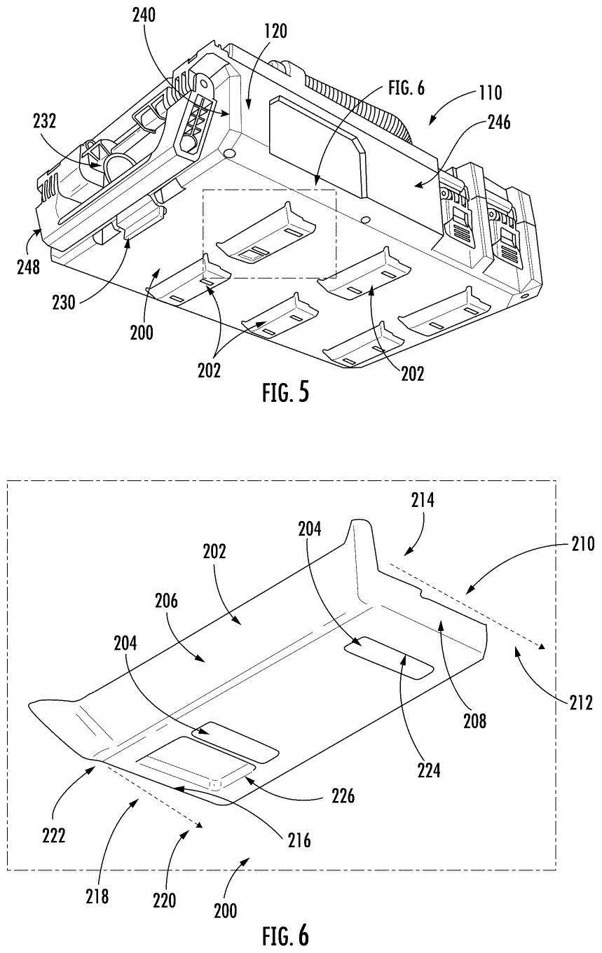

Referring to FIGS. 5-6, device 110 includes bottom surface 200 defined by housing 120, and a plurality of male couplers 202 extending from bottom surface 200 of housing 120, the plurality of male couplers 202 detachably and rigidly couple the housing 120 to a top surface of a storage unit, such as to a storage unit in a modular system. Device 110 includes latch 230 coupled to housing 120, such as slidably coupled to housing 120, and latch interface 232 configured to facilitate a user actuating latch 230 upward so latch 230 does not extend below bottom surface 200. In various embodiments, latch 230 is coupled to front wall 240 of housing 120. In use, housing 120 is slid in a first direction until male couplers 202 engage with coupling mechanisms, such as female couplers on a top surface of a modular unit, until latch 230 engages with a latch recess defined by the modular unit. Latch 230 is configured to engage with a latch recess defined by the top surface of the storage unit the device 110 is coupled to. Engagement between the latch 230 and the latch recess biases male couplers 202 from disengaging from the female couplers, thereby result in device 110 and the modular unit being detachably and rigidly coupled together.

Referring to FIG. 6, one or more of male couplers 202 include engagement components 204 extending from and below body 206 of male coupler 202. In various embodiments, engagement components 204 are formed from a material (e.g., rubber) that provides increased frictional resistance between housing 120 and the object that device 110 is resting on, thereby biasing device 110 from sliding with respect to the object that device 110 is resting on. In various embodiments, engagement components 204 are detachably coupled to housing 120, and thus are replaceable by a user.

Device 110 includes bottom surface 200 defined by housing 120. In various embodiments each of the plurality of male couplers 202 includes a body 206 extending from the bottom surface 200, a first tongue 208, and a second tongue 216. The first tongue 208 and the second tongue 216 both extend from the body 206 and both are offset from, below, and parallel to the bottom surface 200. The first tongue 208 defines a first channel 210 between the bottom surface 200 and the first tongue 208, and the second tongue 216 defines a second channel 218 between the bottom surface 200 and the second tongue 216. The first channel 210 and second channel 218 each extend on opposing sides (e.g., first side 224 and opposing second side 226) of the body 206.

Each of first channel 210 and second channel 218 includes a front open end and a back closed end. For example, first channel 210 extends from back closed end 214 to a front open end 212, and second channel 218 extends from back closed end 222 to front open end 220.

In various embodiments, first channel 210 extends from the closed back end 214 towards the front open end 212 and the back wall 242 of housing 120.

In a specific embodiment, male couplers 202 and latch 230 are compatible with the coupling mechanism(s) described in International Patent International Patent Publication No. WO/2017/191628, which is hereby incorporated by reference in its entirety.

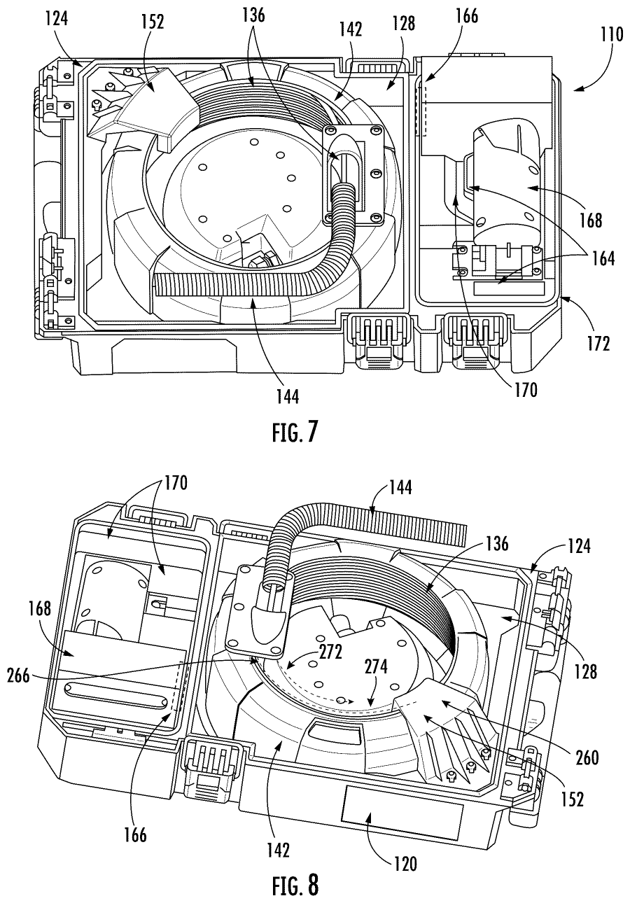

Referring to FIGS. 7-8, various aspects of the internal structure of device 110 are shown. Gasket 124 engages first lid 122 and housing 120 when first lid 122 is in the closed position with respect to housing 120 to provide a seal between first lid 122 and housing 120. In various embodiments, gasket 124 engages between first lid 122 and housing 120 to reduce the amount of debris and/or water that passes between first lid 122 and housing 120 to escape or enter first compartment 128. Gasket 172 engages second lid 160 and housing 120 when second lid 160 is in the closed position with respect to housing 120 to provide a seal between second lid 160 and housing 120. In various embodiments, gasket 172 engages between second lid 160 and housing 120 to reduce the amount of debris and/or water that passes between second lid 160 and housing 120 to escape or enter second compartment 164.

First lid 122 and housing 120 collectively define first compartment 128. First compartment 128 includes drum 142, which secures cable 136 within first compartment 128. In various embodiments, first lid 122 and the housing 120 collectively define a first compartment 128 configured to store a cable 136 coupled to the camera 140.

Second lid 160 and housing 120 collectively define a compartment, such as second compartment 164, and storage area 170. Second lid 160 and housing 120 define second compartment, in which battery interface 166 is located. Second compartment 164 includes battery interface 166 that is configured to physically and electrically couple to rechargeable power tool battery 168. In various embodiments, display 130 and camera 140 are configured to receive power from the rechargeable power tool battery 168 coupled to battery interface 166. Second compartment 164 includes storage area 170 configured to store other objects and/or equipment, such as skids or other small drain cleaning accessories.

Device 110 includes retainer 152 extending from housing 120 to secure cable 136 within drum 142. In various embodiments, retainer 152 extends from housing 120 towards a center of drum 142 and then downward, thereby securing cable 136 within drum 142.

When cable 136 is being retracted into drum 142, cable 136 enters drum 142 in direction 272 via input 266. Retainer 152 is positioned on drum 142 at angle 274 with respect to input 266 in direction 272 circumferentially around drum 142. In various embodiments, angle 274 is between 90 degrees and 270 degrees, and more specifically between 100 degrees and 180 degrees, and more specifically between 110 degrees and 160 degrees, and even more specifically is 135 degrees. Applicant has observed that these angles 274 facilitate retainer 152 holding cable 136 within drum 142 as cable 136 is being retracted into drum 142.

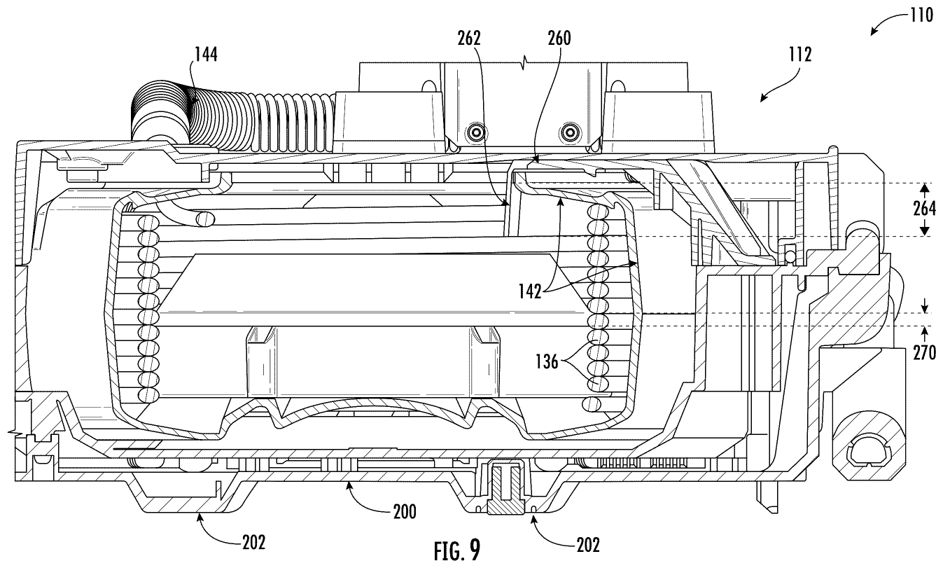

Referring to FIG. 9, various aspects of retainer 152 are shown. Retainer 152 includes horizontal arm 260 that extends horizontally above drum 142 between drum 142 and first lid 122, and retainer 152 includes vertical arm 262 extending from horizontal arm 260 away from first lid 122 and towards bottom surface 200. In various embodiments, vertical arm 262 extends distance 264 into drum 142, and distance 264 is at least two times diameter 270 of cable 136, and more specifically distance 264 is at least three times diameter 270 of cable 136, and even more specifically vertical arm 262 extends to the bottom of drum 142 thereby enclosing cable 136 between vertical arm 262 and the inner surface of drum 142.

In various embodiments, horizontal arm 260 interfaces against first lid 122 when first lid 122 is closed, and the interface between horizontal arm 260 and first lid 122 helps bias retainer 152 downward towards bottom surface 200. First lid 122 biasing retainer 152 downward towards bottom surface 200 helps keep retainer 152 in position to restrain cable 136 within drum 142. In various embodiments, device 110 includes a drum 142 located within first compartment 128, cable 136 being wrapped within the drum 142, and device 110 includes retainer 152 including a vertical arm 262 that extends away from the first lid 122 and within the drum 142, the vertical arm 262 partially enclosing the cable 136 within the drum 142.

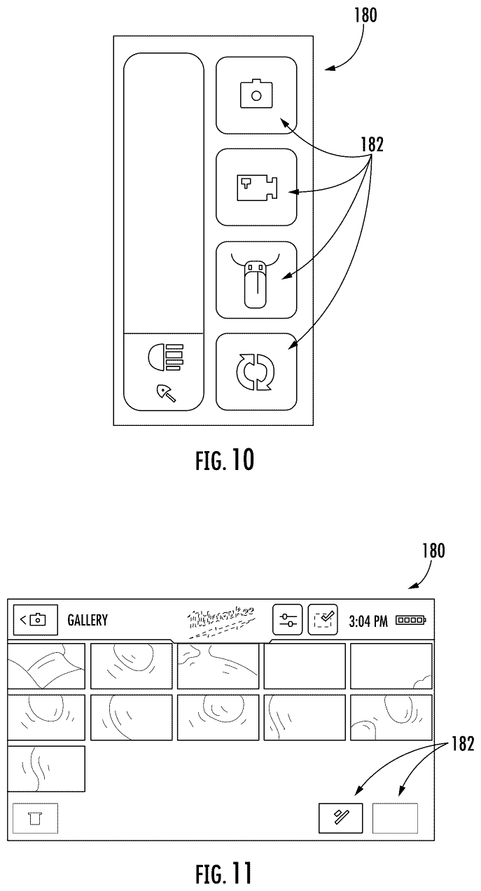

Referring to FIG. 10, in various embodiments, buttons 182 on screen 180 have a transparent or mostly transparent background and/or buttons 182 include an outline to identify the tappable area of the button 182, such as when display 130 is a touch-screen display.

Referring to FIG. 11, in various embodiments, buttons 182 on screen 180 are brighter relative to other buttons 182 when the button 182 is selected, and buttons 182 are darker relative to other buttons 182 when the button 182 is not selected.

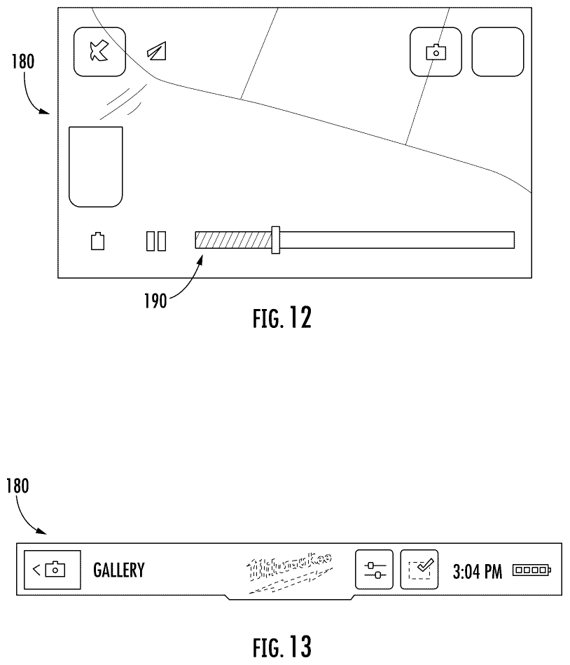

Referring to FIG. 12, in various embodiments, sliders 190 are large enough for a user's finger to be able to easily interact with the screen 180. In various embodiments, one side of sliders 190 are colored and/or brighter to indicate to the user the extent that the control has been activated.

Referring to FIG. 13, in various embodiments, the screen 180 displays a status bar that indicates various pieces of important information, such as battery life remaining, Wi-Fi connectivity, and/or the time.

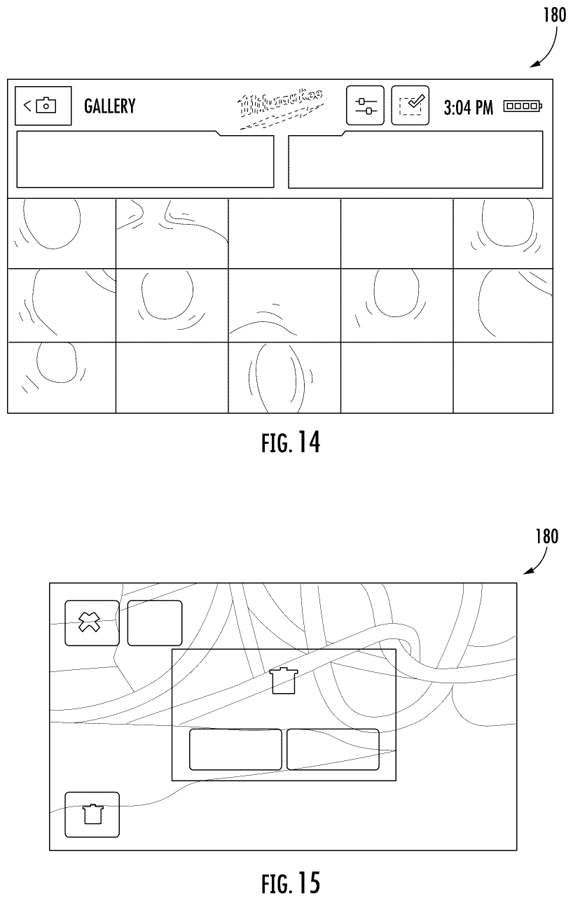

Referring to FIGS. 14-15, in various embodiments, screen 180 facilitates transitions for users, such as by providing a list of filter options at a top of the screen (FIG. 14), and/or by providing a pop-up alert overlayed on the screen 180, such as semi-transparently in the middle of screen 180 (FIG. 15).

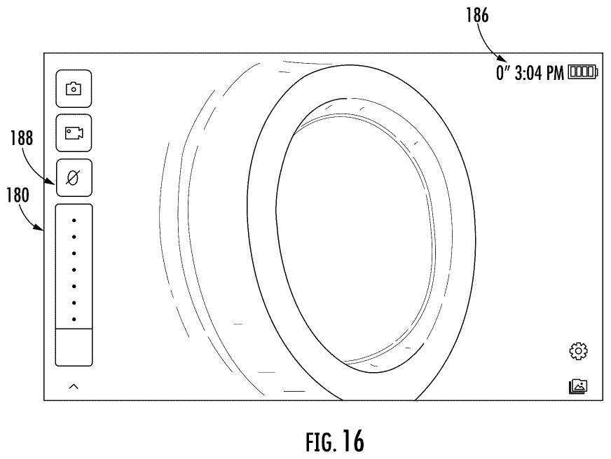

Referring to FIG. 16, in various embodiments, screen 180 includes a distance counter 186 that indicates an amount of cable 136 that has been extended out of housing 120, and/or a zero-out button 188.

It should be understood that the figures illustrate the exemplary embodiments in detail, and it should be understood that the present application is not limited to the details or methodology set forth in the description or illustrated in the figures. It should also be understood that the terminology is for the purpose of description only and should not be regarded as limiting.

Further modifications and alternative embodiments of various aspects of the disclosure will be apparent to those skilled in the art in view of this description. Accordingly, this description is to be construed as illustrative only. The construction and arrangements, shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present disclosure.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more component or element, and is not intended to be construed as meaning only one.

For purposes of this disclosure, the term “coupled” means the joining of two components directly or indirectly to one another. Such joining may be stationary in nature or movable in nature. Such joining may be achieved with the two members and any additional intermediate members being integrally formed as a single unitary body with one another or with the two members or the two members and any additional member being attached to one another. Such joining may be permanent in nature or alternatively may be removable or releasable in nature. As used herein, “rigidly coupled” refers to two components being coupled in a manner such that the components move together in a fixed positional relationship when acted upon by a force.

While the current application recites particular combinations of features in the claims appended hereto, various embodiments of the invention relate to any combination of any of the features described herein whether or not such combination is currently claimed, and any such combination of features may be claimed in this or future applications. Any of the features, elements, or components of any of the exemplary embodiments discussed above may be used alone or in combination with any of the features, elements, or components of any of the other embodiments discussed above.

In various exemplary embodiments, the relative dimensions, including angles, lengths and radii, as shown in the Figures are to scale. Actual measurements of the Figures will disclose relative dimensions, angles and proportions of the various exemplary embodiments. Various exemplary embodiments extend to various ranges around the absolute and relative dimensions, angles and proportions that may be determined from the Figures. Various exemplary embodiments include any combination of one or more relative dimensions or angles that may be determined from the Figures. Further, actual dimensions not expressly set out in this description can be determined by using the ratios of dimensions measured in the Figures in combination with the express dimensions set out in this description.

What is claimed is:

1. A utility module comprising:
a housing;
a bottom surface defined by the housing;
a plurality of male couplers extending from the bottom surface, the plurality of male couplers detachably and rigidly coupling the housing to a top surface of a storage unit;
a display pivotally coupled to the housing;
a cable configured to extend and retract from within the housing; and
a camera coupled to an outer end of the cable, wherein the display displays one or more images captured by the camera.

2. The utility module of claim 1, wherein each of the plurality of male couplers include a body extending from the bottom surface and a first tongue extending from the body, the first tongue offset from, below and parallel to the bottom surface.

3. The utility module of claim 2, the first tongue defining a first channel comprising a front open end and a back closed end.

4. The utility module of claim 3, the housing comprising a front wall and an opposing back wall, the first channel extending from the closed back end towards the front open end and the back wall, the utility module comprising a handle coupled to the front wall.

5. The utility module of claim 3, the housing comprising a front wall and an opposing back wall, the first channel extending from the closed back end towards the front open end and the back wall, the utility module comprising a latch coupled to the front wall, the latch configured to engage with a latch recess defined by the top surface of the storage unit, wherein engagement the latch and the latch recess biases male couplers from disengaging from female couplers of the storage unit.

6. The utility module of claim 1, wherein the display pivots with respect to the housing about a first axis and a second axis distinct from the first axis.

7. The utility module of claim 6, wherein the second axis is perpendicular to the first axis.

8. The utility module of claim 1, comprising a knee padding, the knee padding configured to be used by a user operating the camera and display.

9. The utility module of claim 1, wherein the display is a touchscreen.

10. A utility module comprising:
a housing;
a bottom surface defined by the housing;
a plurality of male couplers extending from the bottom surface, the plurality of male couplers detachably and rigidly coupling the housing to a top surface of a storage unit;
a display pivotally coupled to the housing;
a camera, wherein the display displays one or more images captured by the camera; and
a battery interface configured to physically couple to a rechargeable power tool battery, wherein the display and camera are configured to receive power from the rechargeable power tool battery coupled to the battery interface.

11. The utility module of claim 10, comprising a first lid pivotally coupled to the housing, the first lid and the housing collectively defining a first compartment configured to store a cable coupled to the camera.

12. The utility module of claim 11, comprising a second lid pivotally coupled to the housing, the second lid and the housing collectively defining a second compartment in which the battery interface is located.

13. The utility module of claim 12, comprising knee padding coupled to the second lid, the knee padding configured to be used by a user operating the camera and display.

14. The utility module of claim 11, comprising:
a drum located within the first compartment, wherein the cable is wrapped within the drum; and
a retainer comprising a vertical arm that extends away from the first lid and within the drum, the vertical arm partially enclosing the cable within the drum.

15. The utility module of claim 10, wherein each of the plurality of male couplers include a body extending from the bottom surface, a first tongue extending from the body, and a second tongue opposite the first tongue and extending from the body, each of the first tongue and the second tongue offset from, below and parallel to the bottom surface.

16. The utility module of claim 15, the first tongue defining a first channel and the second tongue defining a second channel, each of the first tongue and the second tongue comprising a front open end and a back closed end.

17. The utility module of claim 16, the housing comprising a front wall and an opposing back wall, each of the first channel and the second channel extending from the closed back end towards the front open end and the back wall, the utility module comprising a latch coupled to the front wall, the latch actuating configured to engage with a latch recess defined by the top surface of the storage unit, wherein engagement the latch and the latch recess biases male couplers from disengaging from female couplers of the storage unit.

18. A utility module comprising:
a housing;
a bottom surface defined by the housing;
a plurality of male couplers extending from the bottom surface, the plurality of male couplers detachably and rigidly coupling the housing to a top surface of a storage unit;
a display pivotally coupled to the housing;
a storage area defined by the housing, the storage area configured to store equipment; and
a camera, wherein the display displays one or more images captured by the camera.

19. The utility module of claim 18, comprising engagement components extending from and below the plurality of male couplers, wherein the engagement components are formed from a material comprising rubber.

20. The utility module of claim 19, wherein the display pivots with respect to the housing about a first axis and a second axis distinct from the first axis, wherein the second axis is perpendicular to the first axis, and wherein the display is a touchscreen.
